(19) United States
(12) Patent Application Publication
(10) Pub. No.: US 2026/0107570 A1
(43) Pub. Date: Apr. 16, 2026

(54) SEMICONDUCTOR DEVICE AND METHOD OF FABRICATING THE SAME

(71) Applicant: Taiwan Semiconductor Manufacturing Company, Ltd., Hsinchu (TW)

(72) Inventors: Hong-Chih Chen, Changhua County (TW); Ta-Chun LIN, Hsinchu (TW); Ming-Heng Tsai, Taipei City (TW); Jhon Jhy Liaw, Hsinchu County (TW)

(73) Assignee: Taiwan Semiconductor Manufacturing Company, Ltd., Hsinchu (TW)

(21) Appl. No.: 18/914,265

(22) Filed: Oct. 14, 2024

(51) Int. Cl. H01L 27/092; H01L 21/8238; H01L 29/417; H01L 29/66; H01L 29/78

(52) U.S. Cl. CPC H10D 84/856; H10D 30/024; H10D 30/62; H10D 30/6219; H10D 84/0193; H10D 84/038

(57) ABSTRACT

A semiconductor device including fin structures, gate structures, epitaxial structures and first insulation cut structures is provided. Each of the fin structures extends linearly and the gate structures linearly extends across the fin structures. The epitaxial structures are disposed on the fin structures and located beside the gate structures. The first insulation cut structures are disposed between the epitaxial structures, wherein two adjacent fin structures of the fin structures and two adjacent gate structures of the gate structures surrounds a closed region and one of the first insulation cut structures is located within the closed region.

### BACKGROUND

Along with quick development of semiconductor industry, integrated circuits have become more complicated in functionality and faster in operation speed, yet more compact in size. The miniaturization of integrated circuits includes reducing spacing between adjacent circuit components, which inevitably increases risk of forming leakage paths between the circuit components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A schematically illustrates the arrangement of some components in a semiconductor device in accordance with some embodiments of the disclosure.

FIG. 1B schematically illustrates the arrangement of some components in a semiconductor device in accordance with some embodiments of the disclosure.

FIG. 2 schematically illustrates a cross-sectional view of a semiconductor device taken along line A-A′ indicated in FIG. 1A in accordance with some embodiments.

FIG. 3 schematically illustrates a cross-sectional view of a semiconductor device taken along line B-B′ indicated in FIG. 1A in accordance with some embodiments.

FIG. 4 schematically illustrates a cross-sectional view of a semiconductor device taken along line A-A′ indicated in FIG. 1A in accordance with some embodiments.

FIG. 5 schematically illustrates a cross-sectional view of a semiconductor device taken along line B-B′ indicated in FIG. 1A in accordance with some embodiments.

FIG. 6 schematically illustrates a cross-sectional view of a semiconductor device taken along line A-A′ indicated in FIG. 1A in accordance with some embodiments.

FIG. 7 schematically illustrates a cross-sectional view of a semiconductor device taken along line B-B′ indicated in FIG. 1A in accordance with some embodiments.

FIG. 8 schematically illustrates a cross-sectional view of a semiconductor device taken along line A-A′ indicated in FIG. 1A in accordance with some embodiments.

FIG. 9 schematically illustrates a cross-sectional view of a semiconductor device taken along line B-B′ indicated in FIG. 1A in accordance with some embodiments.

FIG. 10 to FIG. 13 schematically illustrate partial steps of a method of fabricating a semiconductor device in accordance with some embodiments.

FIG. 14 schematically illustrates a portion of a semiconductor device in accordance with some embodiments of the disclosure.

FIG. 15 schematically illustrates a perspective view of a portion of a semiconductor device corresponding to the line C-C′ indicated in FIG. 14 in accordance with some embodiments.

FIG. 16 schematically illustrates a perspective view of a portion of a semiconductor device corresponding to the line D-D′ indicated in FIG. 14 in accordance with some embodiments.

FIG. 17 schematically illustrates a perspective view of a portion of a semiconductor device corresponding to the line C-C′ indicated in FIG. 14 in accordance with some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a semiconductor device having first insulation cut structures between adjacent epitaxial structures to ensure the isolation of adjacent epitaxial structures. In other words, the adjacent epitaxial structures are prevented from being merged. The isolation of the epitaxial structures is advantageous to improve the yield of the semiconductor device.

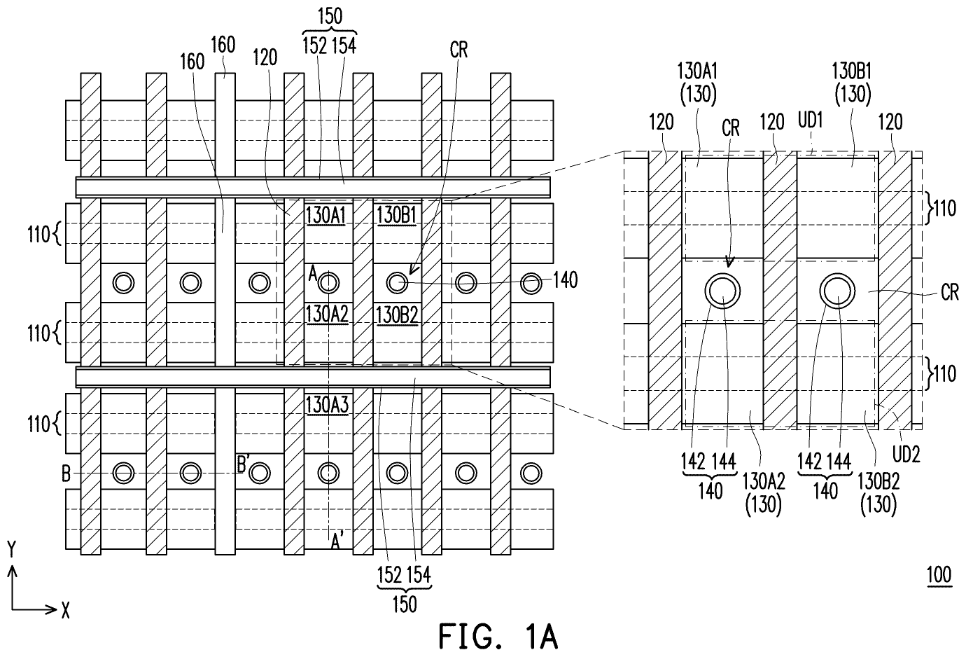

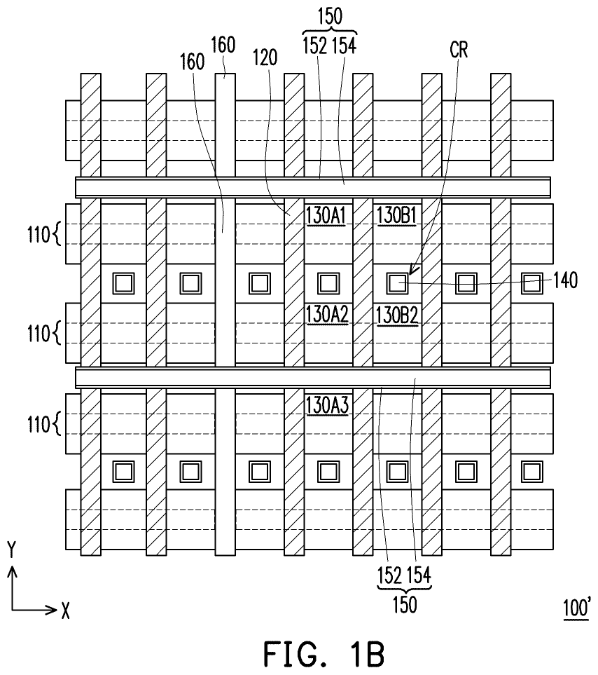

FIG. 1A and FIG. 1B schematically illustrate the arrangement of some components in a semiconductor device in accordance with some embodiments of the disclosure. As shown in FIGS. 1A and 1B and the enlarged portion of FIG. 1A, a semiconductor device 100 at least includes fin structures 110, gate structures 120, epitaxial structures 130 and first insulation cut structures 140. For illustrative purpose, the boundaries of the fin structures 110 are shown by broken lines in FIG. 1 and each of the fin structures 110 extends linearly. The gate structures 120 linearly extend across the fin structures 110. The epitaxial structures 130 are disposed on the fin structures 110 and located beside the gate structures 120. Each of the first insulation cut structures 140 is located between two adjacent epitaxial structures 130 of the epitaxial structures 130 and between two adjacent gate structures 120 of the gate structures 120. The semiconductor device 100′ is similar to the semiconductor device 100, except that the top view shapes of the first insulation cut structures 140 are different in the two drawings. For example, FIG. 1A shows that the top view shapes of the first insulation cut structures 140 are circular and FIG. 1B shows that the top view shapes of the first insulation cut structures 140 are rectangular. In some embodiments, the top view shapes of the first insulation cut structures 140 may have other geometric shapes.

In some embodiments, each of the fin structures 110 extends linearly in a first direction X and the fin structures 110 are substantially arranged in parallel with each other. Each of the gate structures 120 linearly extends along a second direction Y to cross corresponding fin structures 110, for example. In some embodiments, the first direction X and the second direction Y are intersected with each other in a perpendicular manner or in a substantially perpendicular manner, but the disclosure is not limited thereto. In some embodiments, two adjacent fin structures 110 of the fin structures 110 and two adjacent gate structures 120 of the gate structures 120 surrounds a closed region CR and one of the first insulation cut structures 140 is located within the closed region CR. Therefore, each of the first insulation cut structure 140 is located between two different fin structures 110 overlapping the same gate structure 120 and located between two different gate structures 120 overlapping the same fin structure 110. In addition, as shown in FIG. 1A, the first insulation cut structures 140 are distributed in dot-like manner from the plan view without intersecting the gate structures 120 or the fin structures 110.

In some embodiments, a pair of the epitaxial structures 130, are disposed on a common fin structure 110 and located at opposite sides of a common gate structure 120 to define a unit device, such as the unit device UD1 or the unit device UD2. For example, the unit device UD1 includes the epitaxial structure 130A1 and the epitaxial structure 130B1 located at opposite sides of the common gate structure 120 crossing one fin structure 110 and the unit device UD2 includes the epitaxial structure 130A2 and the epitaxial structure 130B2 located at opposite sides of the common gate structure 120 crossing another fin structure 110.

The unit device UD1 and the unit device UD2 share the common gate structure 120. The epitaxial structure 130A1 and the epitaxial structure 130A2 are located at one side of the common gate structure 120, and the epitaxial structure 130B1 and the epitaxial structure 130B2 are located at an opposite side of the common gate structure 120. One of the first insulation cut structures 140 is interposed/located between the epitaxial structure 130A1 and the epitaxial structure 130A2 to ensure the epitaxial structure 130A1 is separated/isolated the epitaxial structure 130A2. Similarly, another first insulation cut structure 140 is interposed/located between the epitaxial structure 130B1 and the epitaxial structure 130B2 to ensure the epitaxial structure 130B1 is separated/isolated the epitaxial structure 130B2. Accordingly, the first insulation cut structures 140 are respectively located between two adjacent epitaxial structures 130 disposed on different fin structures 110 at a same side of the gate structure 120. With the disposition of the first insulation cut structures 140, the independency of the unit devices UD1 and UD2 is ensured, which helps to improve the yield of the semiconductor device 100.

In some embodiments, the unit device UD1 may have a different electric characteristic from the unit device UD2. For example, one is an N-type device and the other is a P-type device. Accordingly, the epitaxial structures 130 of the unit devices UD1 and UD2 have different electric characteristics. Owing that an N-type epitaxial structure and a P-type epitaxial structure may have different feature dimensions, the location of the first insulation cut structures 140 may be asymmetrically arranged between two adjacent fin structures 110. For example, the first insulation cut structure 140 may be closer to the fin structure 110 of the unit device UD1 than the fin structure 110 of the unit device UD2 when the epitaxial structures 130 of the unit device UD1 has a relative smaller feature dimension, and vice versa.

In some embodiments, each of the first insulation cut structures 140 includes a dielectric liner 142 and a dielectric fill 144 surrounded by the dielectric liner 142. The materials of the dielectric liner 142 and the dielectric fill 144 are selected from at least one or a combination of SiO₂, SiCO, SiO₂:F, SiN, SiC, SiCN, other oxide, nitrogen and carbon base materials, or low-k materials. The dielectric liner 142 and the dielectric fill 144 are made of different dielectric materials in some embodiments. For example, the dielectric liner 142 is made of silicon nitride and the dielectric fill 144 is made of silicon oxide, but the disclosure is not limited thereto. In some embodiments, each of the first insulation cut structures 140 is optionally made of a single material and has a one-piece form structure.

In some embodiments, the semiconductor device 100 further includes second insulation cut structures 150 extending in the first direction X and parallel to the fin structures 110. The gate isolation structures 150 cut a previously formed gate feature into the individual gate structures 120. Accordingly, the gate structures 120 in a common column along the second direction Y are separated/isolated from each other by the second insulation cut structures 150, and the gate structures 120 ends/terminates at the second insulation cut structures 150. In other words, an end of one gate structure 120 reaches and is in contact with one second insulation cut structure 150.

In some embodiments, the first insulation cut structures 140 are located between two adjacent fin structures 110 of the fin structures 110 while the second insulation cut structures 150 are located between another two adjacent fin structures 110 of the fin structures 110, but the disclosure is not limited thereto. In some embodiments, each of the gate structures 120 extends across two or more of the fin structures 110, but the disclosure is not limited thereto. In some embodiments, each of the second insulation cut structures 150 includes, for example, a dielectric liner 152 and a dielectric fill 154 surrounded by the dielectric liner 152. The materials of the dielectric liner 152 and the dielectric fill 154 are selected from at least one or a combination of SiO₂, SiCO, SiO₂:F, SiN, SiC, SiCN, other oxide, nitrogen and carbon base materials, or low-k materials. The dielectric liner 152 is made of a dielectric materials different from the dielectric fill 154 in some embodiments. For example, the dielectric liner 152 of the second insulation cut structures 150 and the dielectric liner 142 of the first insulation cut structures 140 are made of the same material, and the dielectric fill 154 of the second insulation cut structures 150 and the dielectric fill 144 of the first insulation cut structures 140 are made of the same material.

In some embodiments, the semiconductor device 100 further includes one or more dielectric gate structure 160. The dielectric gate structure 160 is a dielectric structure and does not function as a gate. Instead, the dielectric gate structure 160 includes one or more dielectric material and function as an isolation feature, in some embodiments. The dielectric gate structure 160 extends in the second direction Y and is parallel to the gate structures 120. That is, the dielectric gate structure 160 has longitudinal axes parallel to the second direction Y. The fin structures 110 arranged in the same row along the first direction X are physically and electrically isolated from one another by the dielectric gate structure 160, in accordance with some embodiments. The fin structures 110 terminates at the dielectric gate structure 160. Therefore, the dielectric gate structure 160 is considered as a feature that cut the fin structures 110. In some embodiments, the dielectric gate structure 160 is configured to prevent leakage between neighboring devices. The dielectric gate structure 160 may be also referred to as continuous poly on diffusion edge (CPODE).

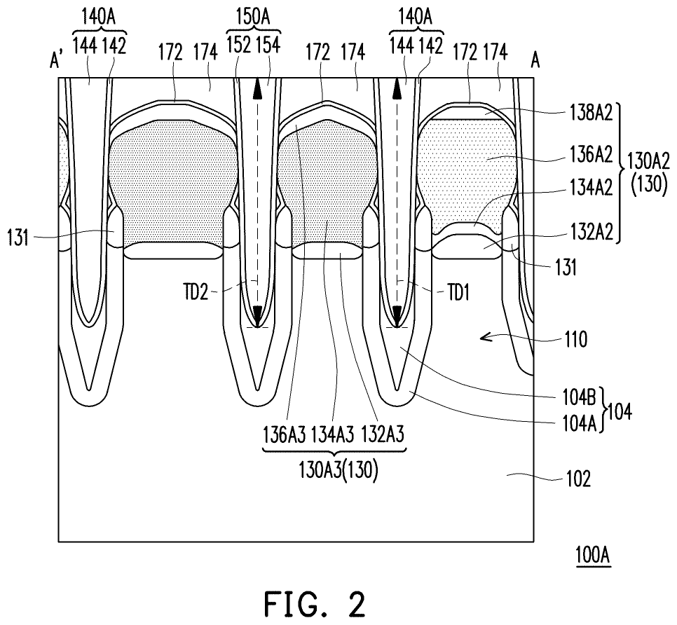

FIG. 2 schematically illustrates a cross-sectional view of a semiconductor device taken along line A-A′ indicated in FIG. 1A in accordance with some embodiments. The semiconductor device 100A includes a substrate 102 and an isolation structure 104 disposed on the substrate 102. The substrate 102 is patterned to have fin structures 110 and the isolation structure 104 fills the space between the fin structures 110, such that the fin structures 110 are surrounded by the isolation structure 104. The epitaxial structures 130 are disposed on the fin structures 110. The first insulation cut structures 140A are disposed over the isolation structure 104 between two adjacent epitaxial structures 130. In some embodiments, each of the first insulation cut structures 140A extends toward the substrate 102 to be partially embedded in the isolation structure 104, but the disclosure is not limited thereto. The second insulation cut structure 150A is located between another two adjacent epitaxial structures 130 and extends toward the substrate 102 to be partially embedded in the isolation structure 104, but the disclosure is not limited thereto.

In some embodiments, the substrate 102 includes a single crystalline semiconductor layer on at least its surface portion. The substrate 102 may include a single crystalline semiconductor material such as, but not limited to Si, Ge, SiGe, GaAs, InSb, GaP, GaSb, InAlAs, InGaAs, GaSbP, GaAsSb and InP. The substrate 102 may include in its surface region, one or more buffer layers (not shown). The buffer layers can serve to gradually change the lattice constant from that of the substrate to that of the source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In some embodiments, the substrate 102 includes silicon germanium (SiGe) buffer layers epitaxially grown on the silicon substrate. The substrate 102 is patterned to have the fin structures 110 thereon.

The isolation structure 104 is formed to fill the spaces between the fin structures 110. The isolation structure 104 includes one or more liner 104A and an isolation insulating layer 104B. In some embodiments, the liner layer 22 includes one or more of silicon nitride, SiON, SiCN, SiOCN, and silicon oxide. The insulating material for the isolation insulating layer 104B may include silicon oxide, silicon nitride, silicon oxynitride (SiON), SiOCN, SiCN, fluorine-doped silicate glass (FSG), or a low-k dielectric material, formed by LPCVD (low pressure chemical vapor deposition), plasma-CVD or flowable CVD. The isolation structure 104 is also called a shallow trench isolation (STI).

In some embodiments, the epitaxial structures 130 are formed on the fin structures 110 that are surrounded by the isolation structure 104. The epitaxial structures 130 and/or the fin structure 110 may be implanted with dopants to form source/drain regions, followed by an anneal. The source/drain regions may have an impurity concentration of between about 10¹⁹ cm⁻³ and about 10²¹ cm⁻³. In some embodiments, the epitaxial structures 130 may be in situ doped during growth. In some embodiments, an insulation portion 131 may be disposed around the bottoms of the fin structures 110, but the disclosure is not limited thereto.

The epitaxial structure 130A2 and the adjacent epitaxial structure 130A3 have different electric characteristics. The epitaxial structure 130A2 is, for example, an epitaxial structure for forming n-type devices, such as NMOS transistors, e.g., n-type FinFETs, and the epitaxial structure 130A3 is, for example, an epitaxial structure for forming p-type devices, such as PMOS transistors, e.g., p-type FinFETs. The epitaxial structure 130A2 may include any acceptable material, such as appropriate for n-type FinFETs. For example, if the fin structure 110 is silicon, the epitaxial structure 130A2 may include materials exerting a tensile strain in the fin structure 110, such as silicon, SiC, SiCP, SiP, or the like. The epitaxial structure 130A3 may include any acceptable material, such as appropriate for p-type FinFETs. For example, if the fin structure 110 is silicon, the epitaxial structure 130A3 may comprise materials exerting a compressive strain in the fin structure 110, such as SiGe, SiGeB, Ge, GeSn, or the like.

The epitaxial structure 130A2 may include silicon and be doped with arsenic (As) or phosphorous (P). Specifically, the epitaxial structure 130A2 includes a first region 132A2, a second region 134A2, a third region 136A, and a fourth region 138A2 sequentially arranged on the fin structure 110. In some embodiments, the epitaxial structure 130A2 may have a fewer or greater number of regions. The first region 132A2, the second region 134A2, the third region 136A2, and the fourth region 138A2 may have different dopant concentrations and/or dopant components.

The epitaxial structure 130A3 may include silicon germanium (SiₓGe₁₋ₓ, where x can be in the range of 0 to 1) doped with boron (B). Specifically, the epitaxial structure 130A3 includes a first region 132A3, a second region 134A3, and a third region 136A3 sequentially arranged on the fin structure 110. In some embodiments, the epitaxial structure 130A3 may have a fewer or greater number of regions. The first region 132A3, the second region 134A3, and the third region 136A3 may have different dopant concentrations and/or dopant components.

In some embodiments, an etching stop layer 172 is further disposed on the substrate 102 to cover the epitaxial structures 130 and an interlayer dielectric (ILD) layer 174 is disposed on the etching stop layer 172. The etching stop layer 172 is made of a silicon nitride-based material, such as SiN, and functions as a contact etch stop layer in the subsequent etching operations. The interlayer dielectric layer 174 continuously extends between the second insulation cut structures 150A and the first insulation cut structures 140A. In some embodiments, the tops of the first insulation cut structures 140A, the tops of the second insulation cut structures 150A and the top of the interlayer dielectric layer 174 are co-leveled.

In some embodiments, the etching stop layer 172 covers the epitaxial structures 130 in a conformal manner to prevent the epitaxial structures 130 from being damaged by the subsequent processes. The first insulation cut structures 140A and the second insulation cut structures 150A are respectively inserted between two adjacent epitaxial structures 130 of the epitaxial structures 130 and formed after the formation of the etching stop layer 172 and the interlayer dielectric layer 174. In some embodiments, a portion of the etching stop layer 172 covering sidewalls of the epitaxial structures 130 is partially removed during the fabrication of the first insulation cut structures 140A and the second insulation cut structures 150A, so that the etching stop layer 172 may be cut by the first insulation cut structures 140A and/or the second insulation cut structures 150A. However, in some alternative embodiments, the etching stop layer 172 may continuously covers the epitaxial structures 130.

The first insulation cut structures 140A includes the dielectric liner 142 and the dielectric fill 144 and the second insulation cut structures 150A includes the dielectric liner 152 and the dielectric fill 154. In some embodiments, the material of the dielectric liner 142, the material of the dielectric liner 152 and the material of the etching stop layer 172 are the same and may be silicon nitride-based material, such as SiN. The first insulation cut structures 140A and the second insulation cut structures 150A are disposed between the fin structures 110. Each of the first insulation cut structures 140A extends toward the substrate 102 to a level lower than bottoms of the epitaxial structures 130, which ensures the isolation of two adjacent epitaxial structures 130. The first insulation cut structure 140A and the second insulation cut structure 150A may partially intrude into the isolation structure 104. The extending depth TD1 of the first insulation cut structure 140A may be greater in the center than in the periphery, but the disclosure is not limited thereto. The extending depth TD2 of the second insulation cut structure 150A may be greater in the center than in the periphery. The first insulation cut structure 140A and the second insulation cut structure 150A may have a variable width that is gradually reduced along with the extending depth. In some embodiments, the extending depth TD2 of the second insulation cut structure 150A may be substantially identical to the extending depth TD1 of the first insulation cut structure 140A. In alternative some embodiments, the extending depth TD2 of the second insulation cut structure 150A may be greater than the extending depth TD1 of the first insulation cut structure 140A.

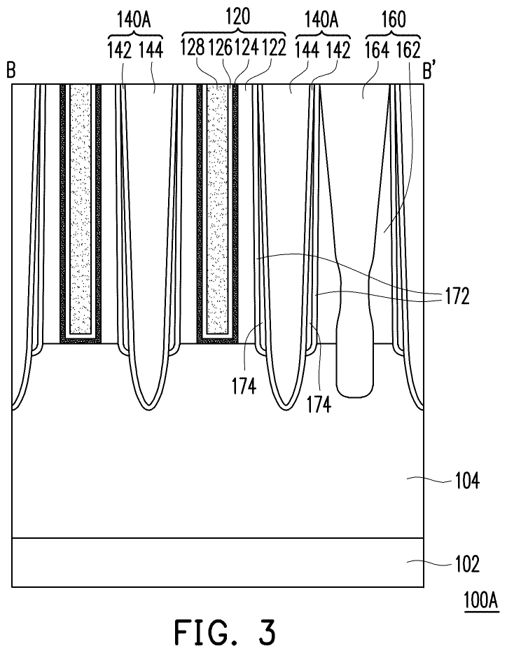

FIG. 3 schematically illustrates a cross-sectional view of a semiconductor device taken along line B-B′ indicated in FIG. 1A in accordance with some embodiments. The components of the semiconductor device 100A indicated by the same reference numbers in FIG. 2 and FIG. 3 refer to the same or substantially the same components and thus the descriptions for the same reference numbers in FIG. 2 and FIG. 3 are able to be incorporated to each other. As shown in FIG. 3, the gate structure 120 in the semiconductor device 100A includes a gate spacer 122, a gate dielectric layer 124, one or more work function layer 126 and a metal fill 128. The gate spacer 122 is disposed on the isolation structure 104 at two opposite sides of the gate structure 120, the gate dielectric layer 124 and the one or more work function layer 126 are disposed along the inner side of the gate spacer 122 and the isolation structure 104 in a conformal manner to form a U shape structure and the metal fill 128 fills the space surrounded by the U shape structure surrounded by the one or more work function layer 126.

The gate spacer 122 may include silicon nitride, silicon carbide, silicon oxynitride, or a combination thereof. The gate spacer 122 may include multiple layers of dielectric material, but the disclosure is not limited thereto. The gate dielectric layer 124 includes silicon oxide, silicon nitride, or multilayers thereof. The gate dielectric layer 124 may include a metal oxide or a silicate of Hf, Al, Zr, La, Mg, Ba, Ti, Pb, and combinations thereof. In some embodiments, the gate dielectric layer 124 is a high-k dielectric material, and may have a k value (dielectric constant) greater than about 7.0. The gate dielectric layer 124 may include a high-k dielectric layer such as hafnium oxide (HfO₂), TiO₂, HfZrO, Ta₂O₃, HfSiO₄, ZrO₂, ZrSiO₂, combinations thereof, or other suitable material. The one or more work function layer 126 may be p-type work function metal materials for PMOS devices or n-type work function metal materials for NMOS devices. Suitable examples of the p-type work function metals, which may have a work function ranging between 4.8 eV and 5.2 eV, include TiN, TaN, Ru, Mo, Al, WN, ZrSi₂, MoSi₂, TaSi₂, NiSi₂, WN, other suitable p-type work function metal materials, and combinations thereof. Suitable examples of the n-type work function metal materials, which may have a work function ranging between 3.9 eV and 4.3 eV, include Ti, Ag, TaAl, TaAlC, HfAl, TiAl, TiAIN, TaC, TaCN, TaSiN, Mn, Zr, other suitable n-type work function metal materials, or combinations thereof. The metal fill 128 may be a metal-containing material such as TiN, TiO, TaN, TaC, Co, Ru, Al, W, Cu, combinations thereof, or multi-layers thereof.

The dielectric gate structure 160 may include the gate spacer 162 and the dielectric gate 164 inserting the gate spacer 162. In some embodiments, the gate spacer 162 and the gate spacer 122 are of the same material and are made through the same process. The dielectric gate 164 extends through the gate spacer 122 to a level lower than the bottom of the gate structures 120. A portion of the dielectric gate 164 extended into and embedded in the isolation structure 104. The dielectric gate structure 160 is made of dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the dielectric gate structure 160 includes dielectric material with k-value greater than 9, such as LaO, AlO, AlON, ZrO, HfO, ZnO, ZrN, ZrAlO, TiO, TaO, YO, and/or TaCN. In some embodiments, the gat isolation structures 150A also cut the dielectric gate structure 160 into segments, but the disclosure is not limited thereto.

As shown in FIG. 3, the tops of the gate structures 120, the first insulation cut structure 140A and the dielectric gate structure 160 are co-leveled. The first insulation cut structure 140A is disposed on isolation structure 104 and extends toward the substrate 102 to a level lower than the gate structures 120. The etching stop layer 172 may be cut by the first insulation cut structure 140A and the bottom of the first insulation cut structure 140A is lower than the bottom of the etching stop layer 172. In some embodiments, the dielectric liner 142 of the first insulation cut structure 140A is in direct contact with the etching stop layer 172. In some embodiments, a portion of the interlayer dielectric layer 174 may be disposed between the dielectric liner 142 of the first insulation cut structure 140A and the etching stop layer 172, but the disclosure is not limited thereto.

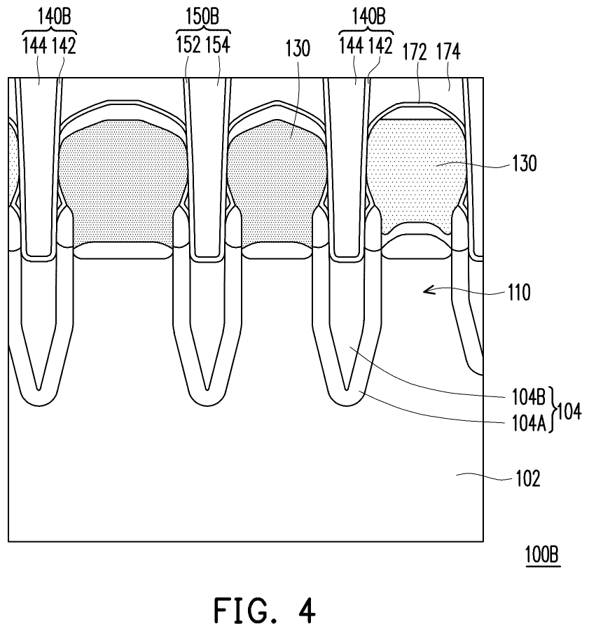

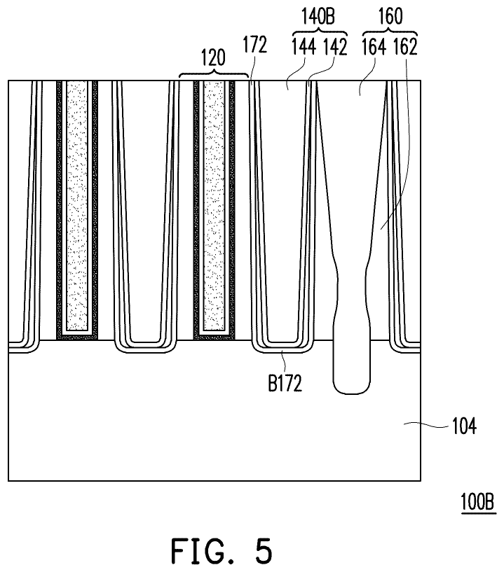

FIG. 4 schematically illustrates a cross-sectional view of a semiconductor device taken along line A-A′ indicated in FIG. 1A. FIG. 5 schematically illustrates a cross-sectional view of a semiconductor device taken along line B-B′ indicated in FIG. 1A in accordance with some embodiments. The semiconductor device 100B shown in FIG. 4 and FIG. 5 is similar to the semiconductor device 100A shown in FIG. 2 and FIG. 3. Similar or identical reference numbers in the embodiments depicted in FIGS. 2 to 5 presents the same or substantially the same components and the descriptions for these components are applicable to each other.

In FIG. 4 and FIG. 5, the semiconductor device 100B includes the substrate 102 having fin structures 110, the isolation structure 104 disposed on the substrate 102 and surrounding the fin structures 110, the gate structures 120 disposed on the substrate 102 and on the isolation structure 104, the epitaxial structures 130 disposed on the fin structures 110, the first insulation cut structures 140B disposed between two adjacent epitaxial structures 130, and the second insulation cut structures 150B disposed between another two adjacent epitaxial structures 130. The semiconductor device 100B further includes the dielectric gate structure 160 disposed in a manner similar to the gate structures 120. The etching stop layer 172 is further disposed on the substrate 102, a portion of the etching stop layer 172 covers the epitaxial structures 130, and a portion of the etching stop layer 172 is disposed between the gate structures 120/the dielectric gate structure 160 and the first insulation cut structure 140B/the second insulation cut structure 150B. The interlayer dielectric layer 174 is disposed on the etching stop layer 172 over the epitaxial structures 130. The tops of the etching stop layer 172, the interlayer dielectric layer 174, the first insulation cut structures 140B, the second insulation cut structures 150B, the gate structures 120 and the dielectric gate structure 160 may extend to a common level.

In some embodiments, the first insulation cut structures 140B and the second insulation structures 150B are similar to the first insulation cut structures 140A and the second insulation structures 150A shown in FIG. 2 and FIG. 3, but extend to a different level. As shown in FIG. 5, the first insulation cut structures 140B extend to a level to reach the etching stop layer 172 without penetrate the etching stop layer 172. The etching stop layer 172 has a bottom portion B172 to form a U-shaped pattern between two gate structures 120 (dielectric gate structure 160). The first insulation cut structures 140B are disposed in the U-shaped pattern of the etching stop layer 172. In addition, the second insulation cut structure 150B extends to substantial the same level as the first insulation cut structures 140B. In some embodiments, the dielectric gate structure 160 may extend to a level lower than the first insulation cut structures 140B, but the disclosure is not limited thereto. In some embodiments, as shown in FIG. 4, the dielectric liner 142 of the first insulation cut structures 140B and the dielectric liner 152 of the second insulation cut structures 150B may be in contact with a portion of the sidewall of the epitaxial structures 130.

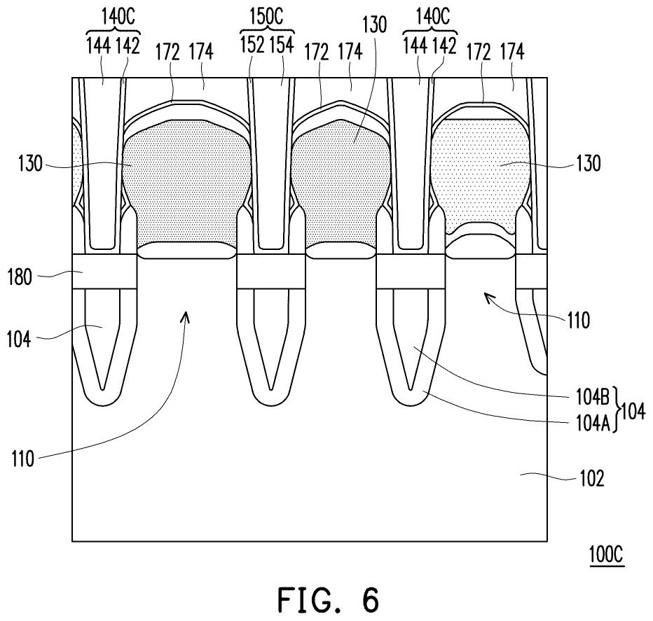

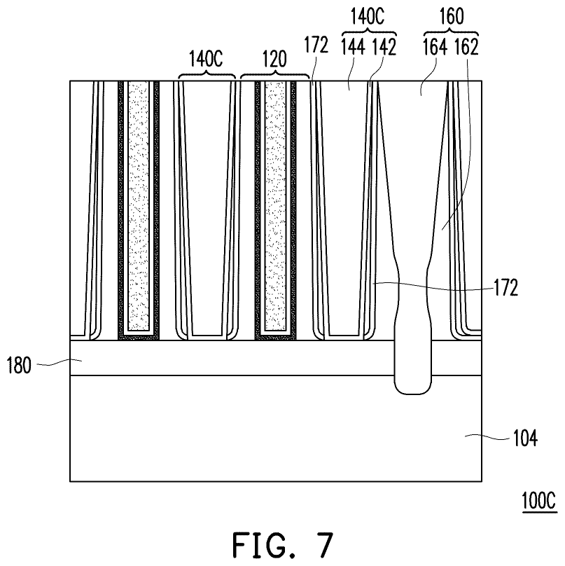

FIG. 6 schematically illustrates a cross-sectional view of a semiconductor device taken along line A-A′ indicated in FIG. 1A. FIG. 7 schematically illustrates a cross-sectional view of a semiconductor device taken along line B-B′ indicated in FIG. 1A in accordance with some embodiments. The semiconductor device 100C shown in FIG. 6 and FIG. 7 is similar to the semiconductor device 100A shown in FIG. 2 and FIG. 3. Similar or identical reference numbers in the embodiments depicted in FIGS. 2, 3, 6 and 7 present the same or substantially the same components and the descriptions for these components are applicable to each other.

In FIG. 6 and FIG. 7, the semiconductor device 100C includes the substrate 102 having fin structures 110, the isolation structure 104 disposed on the substrate 102 and surrounding the fin structures 110, the gate structures 120 disposed on the substrate 102 and on the isolation structure 104, the epitaxial structures 130 disposed on the fin structures 110, the first insulation cut structures 140C disposed between two adjacent epitaxial structures 130, the second insulation cut structures 150C disposed between another two adjacent epitaxial structures 130, the dielectric gate structure 160 disposed in a manner similar to the gate structures 120, the etching stop layer 172, and the interlayer dielectric layer 174.

The etching stop layer 172 is disposed on the substrate 102, a portion of the etching stop layer 172 covers the epitaxial structures 130, and a portion of the etching stop layer 172 is disposed between the gate structures 120/the dielectric gate structure 160 and the first insulation cut structure 140B/the second insulation cut structure 150B. The interlayer dielectric layer 174 is disposed on the etching stop layer 172. The etching stop layer 172, the interlayer dielectric layer 174, the first insulation cut structures 140C, the second insulation cut structures 150C, the gate structures 120 and the dielectric gate structure 160 may extend to a common level over the epitaxial structures 130. In other words, the tops of the etching stop layer 172, the interlayer dielectric layer 174, the first insulation cut structures 140C, the second insulation cut structures 150B, the gate structures 120 and the dielectric gate structure 160 are coplanar.

In addition, the semiconductor device 100C further includes a hark mask layer 180 disposed on the isolation structure 104. In some embodiments, the material of the hark mask layer 180 has a high etching selection rate with respect to the etching stop layer 172. For example, the material of the hark mask layer 180 includes AlOx, but the disclosure is not limited thereto. The first insulation cut structures 140C and the second insulation cut structure 150C extend to reach the hard mask layer 180. The dielectric liner 142 of each first insulation cut structure 140C and the dielectric liner 152 of each second insulation cut structure 150C form respective U-shaped patterns and the bottom of each U-shaped pattern extends along the surface of the hark mask layer 180. In some embodiments, the etching stop layer 172 also reaches the hard mask layer 180 beside the first insulation cut structures 140C and the second insulation cut structure 150C. In some alternative embodiments, a portion of the etching stop layer 172 optionally extends along the hard mask layer 180, such that the portion of the etching stop layer 172 is interposed the bottoms of the first insulation cut structures 140C and the second insulation cut structure 150C and the hard mask layer 180. Accordingly, in some embodiments, the etching stop layer 172 may have a U-shaped pattern surrounding the first insulation cut structures 140C or the second insulation cut structure 150C.

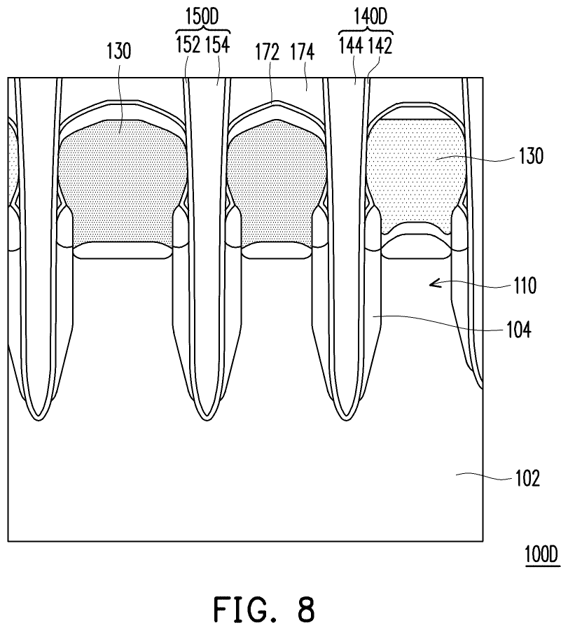

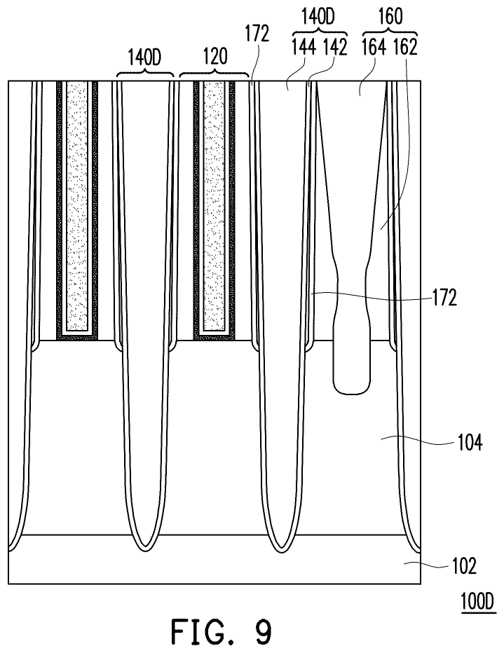

FIG. 8 schematically illustrates a cross-sectional view of a semiconductor device taken along line A-A′ indicated in FIG. 1A in accordance with some embodiments. FIG. 9 schematically illustrates a cross-sectional view of a semiconductor device taken along line B-B′ indicated in FIG. 1A in accordance with some embodiments. The semiconductor device 100D shown in FIG. 8 and FIG. 9 is similar to the semiconductor device 100A shown in FIG. 2 and FIG. 3. Similar or identical reference numbers in the embodiments depicted in FIGS. 2, 3, 8 and 9 present the same or substantially the same components and the descriptions for these components are applicable to each other.

In FIG. 8 and FIG. 9, the semiconductor device 100D includes the substrate 102 having fin structures 110, the isolation structure 104 disposed on the substrate 102 and surrounding the fin structures 110, the gate structures 120 disposed on the substrate 102 and on the isolation structure 104, the epitaxial structures 130 disposed on the fin structures 110, the first insulation cut structures 140D disposed between two adjacent epitaxial structures 130, the second insulation cut structures 150D disposed between another two adjacent epitaxial structures 130, the dielectric gate structure 160 disposed in a manner similar to the gate structures 120, the etching stop layer 172, and the interlayer dielectric layer 174.

As shown in FIG. 8 and FIG. 9, each of the first insulation cut structures 140D and the second insulation cut structure 150D extends toward the substrate 102 to a level lower than the isolation structure 104, such that the bottoms of the first insulation cut structures 140D and the second insulation cut structure 150D is embedded in and in contact with the substrate 102. Each of the first insulation cut structures 140D and the second insulation cut structure 150D extends toward the substrate 102 to a lower level than the dielectric gate structure 160 and the dielectric gate structure 160 extends toward the substrate 102 to a lower level than the gate structures 120. In some embodiments, the second insulation cut structure 150D extends toward the substrate 102 to a level slightly lower than the first insulation cut structures 140D, but the disclosure is not limited thereto.

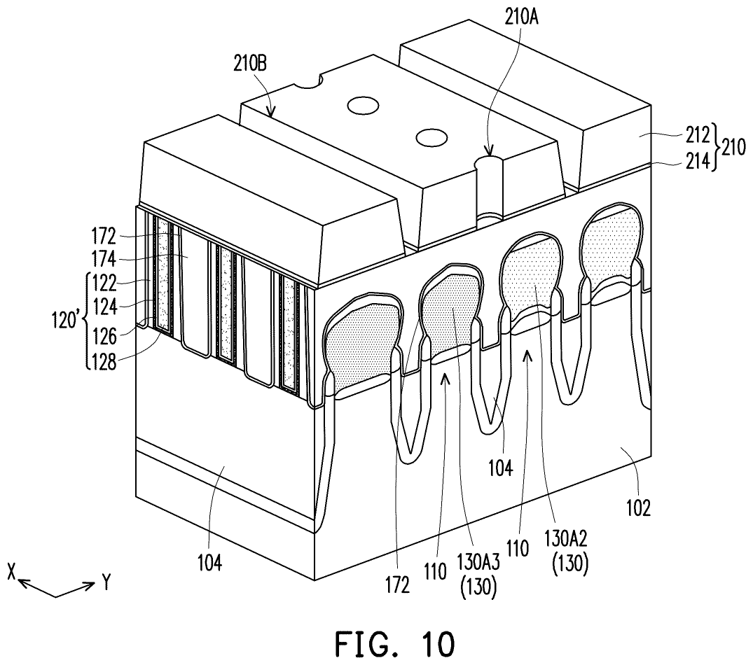

FIG. 10 to FIG. 13 schematically illustrate partial steps of a method of fabricating a semiconductor device in accordance with some embodiments. The components in FIG. 10 to FIG. 13 may be indicated by the same reference numbers depicted in FIGS. 2-5 and thus the descriptions for the components indicated by the same reference numbers in these embodiments are able to be incorporated and/or applicable to each other. The steps shown in FIG. 10 to FIG. 13 provide exemplary examples to fabricate one or more of the semiconductor devices 100, 100A˜100D in the previous embodiments and other alternative embodiments.

In FIG. 10, a substrate 102 is patterned to form the fin structures 110 thereon and the isolation structure 104 is disposed on the substrate 102. Each of the fin structures 110 extends linearly along the first direction X and is surrounded by the isolation structure 104. In some embodiments, a portion of the substrate 102 is etched away to form recesses and isolation material is provided (such as deposited) to fill the recesses to form the fin structures 110 surrounded by the isolation structure 104. The isolation structure 104 may be a shallow trench isolation (STI) structure and/or other suitable isolation structure and made of silicon oxide, silicon nitride, silicon oxynitride, fluoride-doped silicate glass (FSG), a low-k dielectric material, and/or other suitable insulating material. The isolation structure 104 may include a multi-layer structure, for example, includes one or more liner layers. In some embodiments, the isolation structure 104 may have a multi-layer structure such as a thermal oxide liner layer with silicon nitride filling the opening of the thermal oxide liner layer.

The gate features 120′ are subsequently formed on the substrate 102. Each of the gate features 120′ extends along the second direction Y that is intersected with the first direction X. In some embodiments, the first direction X may be perpendicular to the second direction Y. In addition, each of gate features 120′ extends to cross the fin structures 110 to define unit devices by the intersections of the gate features 120′ and the fin structures 110. In some embodiments, each of the gate features 120′ includes a gate spacer 122, a gate dielectric layer 124, one or more work function layer 126 and a metal fill 128. The gate spacer 122 disposed on the isolation structure 104 may include a dielectric material such as silicon oxide. The gate spacer 122 may also include silicon nitride, silicon carbide, silicon oxynitride, or a combination thereof. The gate spacer 122 may have a multi-layer structure in some embodiments. The gate dielectric layer 124 is disposed on the isolation structure 104 and has a U-shape cross section, the one or more work function layer 126 is disposed along the gate dielectric layer 124 to also have a U-shape cross section, and the metal fill 128 is disposed on the one or more work function layer 126 to fill the U-shape cross section of the one or more work function layer 126. In some embodiments, the bottom of the gate dielectric layer 124 may be at a level slightly lower than the gate spacer 122, but the disclosure is not limited thereto.

The epitaxial structures 130 may be formed on the substrate 102 beside the gate features 120′ and the epitaxial structures 130 at one common side of the same gate features 120′ are disposed on different fin structures 110. As shown in FIG. 10, two adjacent epitaxial structures 130 indicated as the epitaxial structures 130A2 and the epitaxial structures 130A3 are disposed at the same side of one of the gate features 120′ and on different fin structures 110. The dopant types and concentrations of the epitaxial structure 130A2 and the epitaxial structure 130A3 may be different to provide different characteristics. In some embodiments, the epitaxial structure 130A2 disposed thereon may serve as a component of an N-type device while the epitaxial structure 130A3 may serve as a component of P-type device, but the disclosure is not limited thereto.

The etching stop layer 172 is formed on the substrate 102 and covers the epitaxial structures 130 in a conformal manner. In addition, the etching stop layer 172 may extend along the isolation structure 104 between the epitaxial structures 130 and between the gate features 120′. The etching stop layer 172 also extends along the sidewalls of the gate spaces 122 of the gate features 120′. The interlayer dielectric layer 174 is deposited to fill the uneven structure covered by the etching stop layer 172. In addition, a planarization process is performed so that the tops of the etching stop layer 172, the interlayer dielectric layer 174 and the gate features 120′ are coplanar and a masking layer 210 is formed on the plane of the tops of the etching stop layer 172, the interlayer dielectric layer 174 and the gate features 120′. In some embodiments, two adjacent epitaxial structures 130 may be merged during the growth of the epitaxial structures 130, such that the etching stop layer 172 may cover the top of the merged epitaxial structures 130 and the merged portion and an underlying portion of the two adjacent epitaxial structures 130 are not covered by the etching stop layer 172.

The masking layer 210 including a photo resist layer 212 and an anti-reflective coating (ARC) 214 is formed on the substrate 102. The masking layer 210 is patterned to have a dot openings 210A and a linear openings 210B. The dot openings 210A and the linear openings 210B pass through the thickness of the masking layer 210 to expose the tops of the etching stop layer 172, the interlayer dielectric layer 174 and the gate features 120′. In some embodiments, the dot openings 210A are arranged along the first direction X and positioned between the epitaxial structures 130. In some embodiments, the dot openings 210A are located between the gate structures without overlapping the gate features 120′. Each of the linear openings 210B extends along the first direction X and positioned between the epitaxial structures 130 while crossing the gate features 120′.

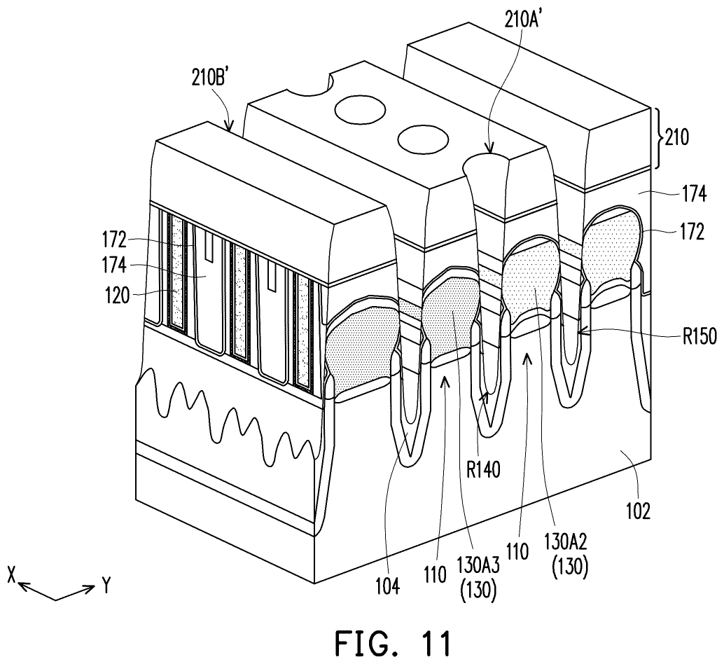

A feature cutting process is performed to remove a portion of the structure exposed by the dot openings 210A and the linear openings 210B to form dot recesses R140 and linear recess R150 over the substrate 102 shown in FIG. 11. Through the feature cutting process, the gate features 120′ are cut into the gate structures 120. The dot openings 210A and the linear openings 210B may be widen to form the dot openings 210A′ and the linear openings 210B′ during the feature cutting process. The dot recesses R140 are formed corresponding to the dot openings 210A′ and the linear recesses R150 are formed corresponding to the linear openings 210B′. In FIG. 11, the dot recesses R140 and the linear recesses R150 may reach the same depth, but the disclosure is not limited thereto. In some embodiments, the linear recesses R150 may reach level lower than the dot recesses R140 since the areas of the linear openings 210B′ is greater than the dot openings 210A′, which results in a greater etching depth, but the disclosure is not limited thereto. The feature cutting process is performed until the etching depth reaches a level lower than the gate features 120′ so that the gate features 120′ exposed by the linear openings 210B′ are cut to form the linear recess R150 and are divided into the gate structures 120. Accordingly, each of the gate structures 120 is terminated at the corresponding linear recess R150. In addition, in some embodiments, one of the epitaxial structure 130A2 and the epitaxial structure 130A3 may be an N-type epitaxial structure while the other may be a P-type epitaxial structure. Owing that an N-type epitaxial structure may have a different feature dimension than a P-type epitaxial structure, the location of the dot recesses R140 may be asymmetrically arranged. For example, the dot recesses R140 may be closer to the fin structure 110 with the epitaxial structure 130A2 thereon than the fin structure 110 with the epitaxial structure 130A3 when the epitaxial structure 130A2 has a relative smaller feature dimension, and vice versa.

In order to remove a portion of the gate features 120′ and other materials exposed by the linear openings 210B′ and the dot openings 210A′, the feature cutting process selects the etchants relatively aggressive so as to remove or etch both the metal containing materials as well as the dielectric materials. The interlayer dielectric layer 174, the etching stop layer 172, and the isolation structure 104 are also removable during the feature cutting process. The etchants selected during the feature cutting process may be relatively aggressive having a relatively low selectivity among the materials from the metal fill 128, the one or more work function layer 126, the gate dielectric layer 124, the gate spacer 122, the etching stop layer 172, and the interlayer dielectric layer 174. As a result, the etchants from the metal gate structure cutting process may globally etch the structures uncovered by the masking layer 210.

In some embodiments, a portion of the etching stop layer 172 originally covers the sidewalls of the epitaxial structures 130 is removed during the feature cutting process. In some embodiments, a thickness of the etching stop layer 172 covering the sidewalls of the epitaxial structures 130 is thinner than thickness of the etching stop layer 172 covering the tops of the epitaxial structures 130 since the material of the etching stop layer 172 is removable during the feature cutting process. In some embodiments, a portion of the sidewalls of the epitaxial structures 130 may be exposed at the dot recesses R140 and/or the linear recesses R150. In some embodiments, two adjacent epitaxial structures 130 are originally merged to connect to each other are isolated from each other by the dot recesses R140 and/or the linear recesses R150 through the feature cutting process. The feature cutting process also refers to an epitaxial structure cutting process, which ensures the isolation of the epitaxial structures 130.

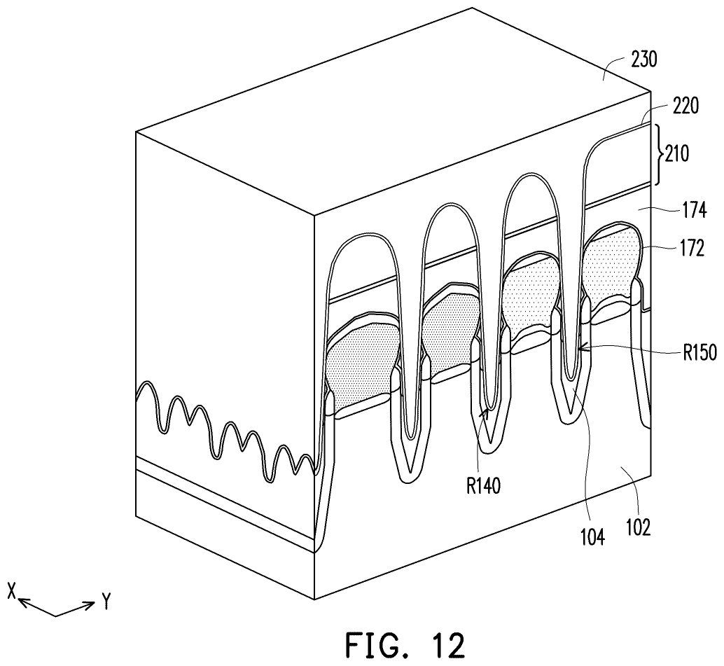

In the subsequent step as shown in FIG. 12, a liner material layer 220 and a filling material 230 are sequentially deposited on the substrate 102. The liner material layer 220 is formed to cover the masking layer 210, the dot recesses R140 and the linear recesses R150 in a conformal manner and the filling material 230 fills the uneven structure of the liner material layer 220 to a level higher than the top of the masking layer 210. Accordingly, the dot recesses R140 and the linear recesses R150 are filled. In some embodiments, the materials of the liner material layer 220 and the filling material 230 are selected from at least one or a combination of SiO₂, SiON, SiN, SiC, SiOC, SiOCN, or low-k materials. In some embodiments, the liner material layer 220 is made of silicon nitride and the filling material 230 is made of silicon oxide, but the disclosure is not limited thereto.

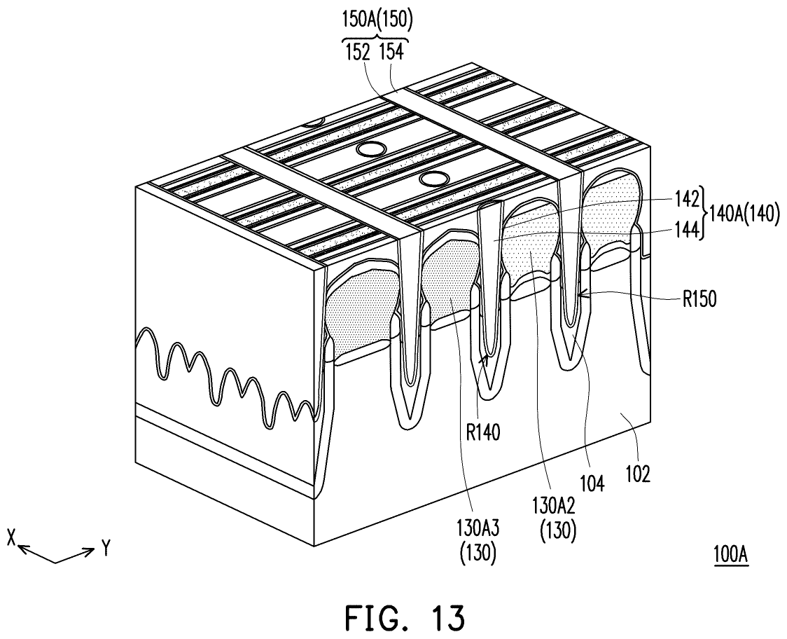

In FIG. 13, a planarization process such as CMP is performed to remove exceeding materials of the liner material layer 220 and the filling material 230 until the gate structures 120 are exposed. The liner material layer 220 and the filling material 230 filling the dot recesses R140 form the first insulation cut structures 140A and the liner material layer 220 and the filling material 230 filling the linear recesses R150 form the second insulation cut structures 150A to obtain a semiconductor device 100A which is similar to the semiconductor device 100A shown in FIG. 2 and FIG. 3. After performing the planarization process, the gate structures 120 are co-level with the first insulation cut structures 140A and the second insulation cut structures 150A. Through the process depicted in FIG. 10 to FIG. 13, the first insulation cut structures 140A and the second insulation cut structures 150A are formed through a feature cutting process which may include forming openings and filling the openings with a dielectric material.

The method of fabricating the semiconductor device 100A shown in FIG. 10 to FIG. 13 is applicable to fabricate any of the semiconductor devices 100B, 100C and 100D. In the embodiment of forming the semiconductor device 100A shown in FIG. 2 and FIG. 3, the feature cutting process is performed until a portion of the isolation structure 104 is removed so that the first insulation cut structures 140A and the second insulation cut structures 150A formed by filling the dot recesses R140 and the linear recesses R150 extend into the isolation structure 104. In the embodiment of forming the semiconductor device 100B shown in FIG. 4 and FIG. 5, the feature cutting process is performed till the dot recesses R140 and the linear recesses R150 reach the etching stop layer 172 so that the etching stop layer 172 remains and covers the isolation structure 104. In the embodiment of forming the semiconductor device 100C shown in FIG. 6 and FIG. 7, a hard mask layer 180 is disposed on the isolation structure 104 before forming the gate structures 120, the etching stop layer 172 and the interlayer dielectric layer 174, and the feature cutting process is performed till the dot recesses R140 and the linear recesses R150 reach the hard mask layer 180. In the embodiment of forming the semiconductor device 100D shown in FIG. 8 and FIG. 9, the feature cutting process is performed till the dot recesses R140 and the linear recesses R150 passing through the isolation structure 104 and reaching the substrate 102.

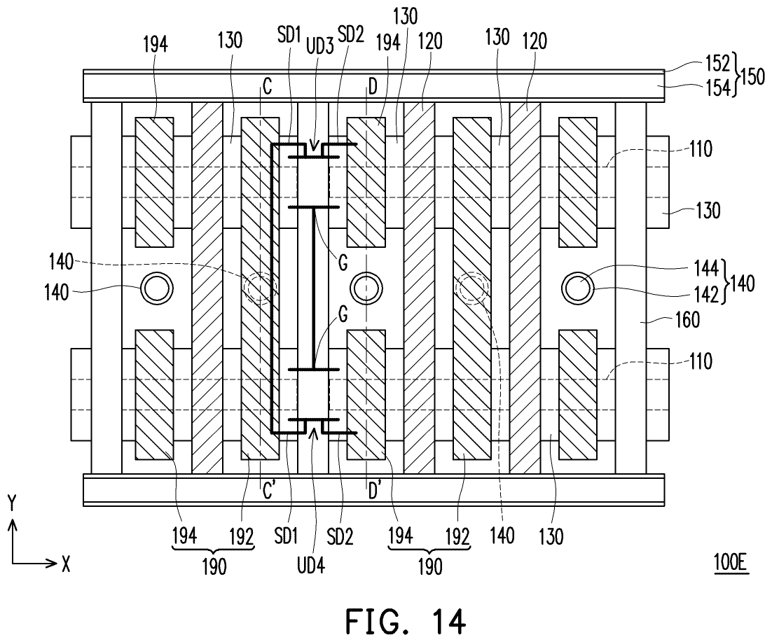

FIG. 14 schematically illustrates a portion of a semiconductor device in accordance with some embodiments of the disclosure. A semiconductor device 100E includes fin structures 110, gate structures 120, epitaxial structures 130, first insulation cut structures 140, second insulation cut structures 150, and dielectric gate structures 160, which are depicted in FIG. 1A. Therefore, the semiconductor device 100E in FIG. 14 is similar to the semiconductor device 100 in FIG. 1A and the descriptions for the same components in the two embodiments may refer to each other. The semiconductor device 100E further includes contact structures 190 located between the gate structures 120/the dielectric gate structures 160. Each of the fin structures 110 extends linearly along the first direction X and each of the gate structures 120/the dielectric gate structures 160 extends along the second direction Y intersecting with the first direction X. The epitaxial structures 130 are disposed along the fin structures 110 and located beside the gate structures 120. Each of the first insulation cut structures 140 is disposed between two adjacent fin structures 110 and between two adjacent gate structures 120 to isolate two adjacent epitaxial structures 130 on different fin structures 110. Each of the gate structures 120 extends to cross tow or more of the fin structures 110 and terminates at the second insulation cut structures 150. Each of the dielectric gate structures 160 cuts the fin structures into segments so that the fin structures 110 terminates at the dielectric gate structures 160. Each of the first insulation cut structures 140 includes a dielectric liner 142 and the dielectric fill 144 surrounded by the dielectric liner 142 and each of the second insulation cut structures 150 includes a dielectric liner 152 and the dielectric fill 154 surrounded by the dielectric liner 152.

The contact structures 190 are disposed on the epitaxial structures 130 to establish the electric transmission of the epitaxial structures 130. At least one of the contact structures 190, such as the contact structure 192, is in contact two of the epitaxial structures 130 on different fin structures 110. In some embodiments, the two of the epitaxial structures 130 electrically connected to each other by the contact structure 192 may be physically isolated from each other by a corresponding one of the first insulation cut structures 140. In some embodiments, the first insulation cut structures 140 overlapping the contact structures 192 are optionally omitted and thus are presented by broken lines. The contact structures 190 further include the contact structures 194 that are in contact with the epitaxial structures 130 in a one-to-one manner. Accordingly, each of the contact structures 194 is in contact with a single one of the epitaxial structures 130. For two of the contact structures 194 arranged in the same line, one of the first insulation cut structures 140 isolating two adjacent epitaxial structures 130 is located between the two of the contact structures 194.

In some embodiments, each of the epitaxial structures 130 serves as a source/drain and each of the gate structure serves as a gate G, such that at least one unit device UD3 and at least one unit device UD4 are defined. As shown in FIG. 14, the epitaxial structures 130 located at opposite sides of the gate G of the unit device UD3 form the first source/drain SD1 and the second source/drain SD2. Similarly, the epitaxial structures 130 located at opposite sides of the gate G of the unit device UD4 form the first source/drain SD1 and the second source/drain SD2. The first source/drain SD1 of the unit device UD3 and the first source/drain SD1 of the unit device UD4 are electrically connected through the contact structure 192. The second source/drain SD1 of the unit device UD3 and the second source/drain SD2 of the unit device UD4 are independently electrically connected to respective contact structures 194. By the arrangement of the contact structures 190, the unit devices in the semiconductor device 100E are electrically connected in a prescribed manner to form the required circuit such as the logic circuits, the SRAM circuit, or other circuits.

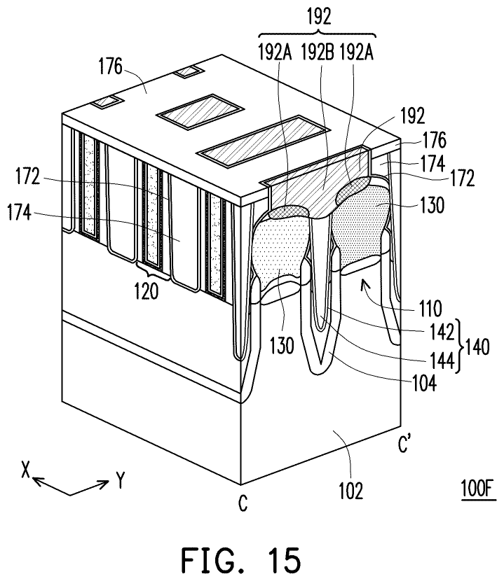

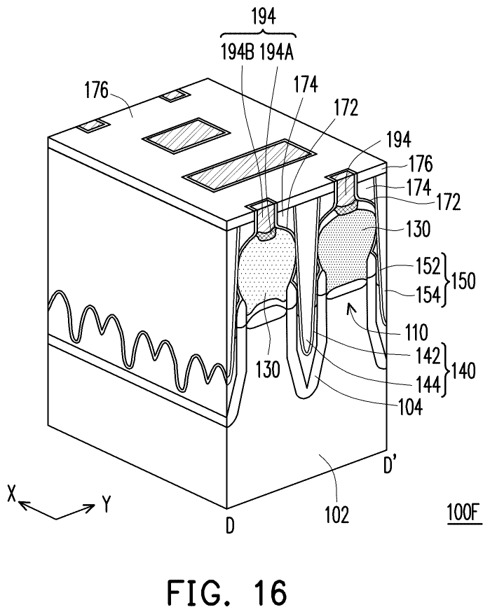

FIG. 15 schematically illustrates a perspective view of a portion of a semiconductor device corresponding to the line C-C′ indicated in FIG. 14 in accordance with some embodiments. FIG. 16 schematically illustrates a perspective view of a portion of a semiconductor device corresponding to the line D-D′ indicated in FIG. 14 in accordance with some embodiments. A semiconductor device 100F shown in FIG. 15 and FIG. 16 includes a substrate 102 with the fin structures 110, an isolation structure 104 disposed on the substrate 102 to surround the fin structures 110, the epitaxial structures 130 disposed on the fin structures 110, the first insulation cut structures 140 disposed on the isolation structure 104 between two adjacent epitaxial structures 130 on different fin structures 110, the second insulation cut structures 150 disposed on the isolation structure 104, the contact structures 192 disposed on a portion of the epitaxial structures 130, and the contact structures 194 disposed on another portion of the epitaxial structures 130. In addition, the semiconductor device 100F further includes an etching stop layer 172 partially covering the epitaxial structures 130, an interlayer dielectric layer 174 disposed on the etching stop layer 172, and an insulation layer 176 disposed on the etching stop layer 172 and the interlayer dielectric layer 174. Some of the components in FIG. 15 and FIG. 16 share the same reference numbers depicted in the previous embodiments, and the descriptions for these components in any of the previous embodiments are applicable to the embodiment of FIG. 15 and FIG. 16.

In FIG. 15 and FIG. 16, the contact structures 192 and the contact structures 194 extends to pass through the insulation layer 176, the interlayer dielectric layer 174 and the etching stop layer 172 to be in contact with the corresponding epitaxial structures 130. Each of the contact structures 192 in contact with two epitaxial structures 130 may include silicide regions 192A in direct contact with the two epitaxial structures 130 and a metal region 192B on the silicide regions 192A. Each of the contact structures 194 in contact with one single epitaxial structure 130 may include a silicide region 194A in direct contact with the corresponding epitaxial structure 130 and a metal region 194B on the silicide regions 194A. The contact structures 192 and the contact structures 194 are formed by depositing a metal material on the exposed surface of the epitaxial structures 130, in which the silicide regions 192A and the silicide regions 194A are formed by reacting a surface portion of the epitaxial structures 130 with the metal material.

One of the first insulation cut structures 140 is located under the contact structure 192 as shown in FIG. 15. The bottom of each of the contact structures 192 may be in contact with the corresponding first insulation cut structure 140. Specifically, the bottom of each of the contact structures 192 is in contact with the dielectric liner 142 as well as the dielectric fill 144. The silicide regions 192A is absent on the first insulation cut structures 140 and the metal region 192B is in direct contact with the dielectric liner 142 as well as the dielectric fill 144.

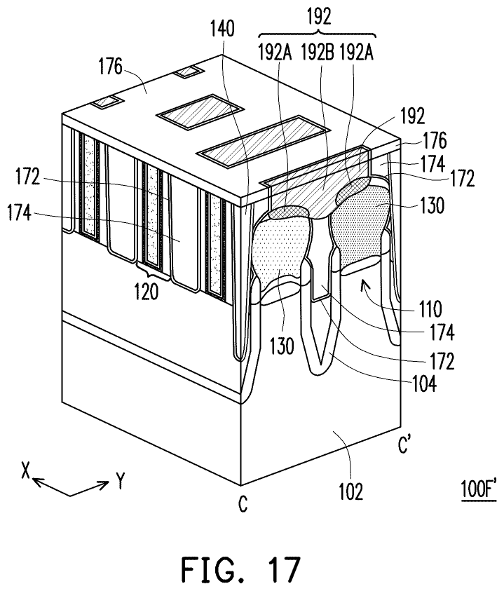

FIG. 17 schematically illustrates a perspective view of a portion of a semiconductor device corresponding to the line C-C′ indicated in FIG. 14 in accordance with some embodiments. A semiconductor device 100F′ is similar to the semiconductor device 100F shown in FIG. 15 and the difference between the two embodiments lies in that the first insulation cut structure 140 under the contact structure 192 in the semiconductor device 100F is omitted from the semiconductor device 100F′. Specifically, in the semiconductor device 100F′, the interlayer dielectric layer 174 surrounded by the etching stop layer 172 is disposed between the epitaxial structures 130 connected to a common contact structure 192 and the bottom of the contact structure 192 is in contact with the interlayer dielectric layer 174 and the etching stop layer 172. The bottom of the contact structure 192 in contact with the interlayer dielectric layer 174 may be lower than the bottom of the contact structure 192 in contact with the corresponding epitaxial structures 130. The contact structure 192 may include silicide regions 192A in direct contact with the epitaxial structures 130 and a metal region 192B on the silicide regions 192A. The silicide regions 192A are absent on the first insulation cut structures 140 and the metal region 192B is in direct contact with the interlayer dielectric layer 174 and the etching stop layer 172.

In some embodiments, the semiconductor device 100E, the semiconductor device 100F and the semiconductor device 100F′ can be fabricated by using the method depicted in FIG. 10 to FIG. 13. In addition, the first insulation cut structures 140 and the second insulation cur structures 150 in the semiconductor device 100E, the semiconductor device 100F and the semiconductor device 100F′ may have similar structures of the first insulation cut structures 140A˜140D and the second insulation cur structures 150A˜150D presented in FIG. 2 to FIG. 9.

Also, the semiconductor devices in various embodiments described above may be implemented by GAA FETs, fin-type FETs (FinFETs), Forksheet FETs, complementary EFTs (CFET) or planar-type FETs, without changing the layout design. The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. For GAA FETs, the fin structures 110 overlapping the gate structures 120 may include a stack of nano sheets or nano rods that are surrounded by the gate structures 120 and serve as channel regions. In some embodiments, a channel region of a FinFET is provided by one or more fin structures 110 defined on the substrate 102, rather than a stack of the nano structures. In some embodiments, a channel region of a planar-type FET is provided by a doped region formed inside the semiconductor substrate 200. In addition, the semiconductor devices in various embodiments may form different circuits such as a logic circuit or a SRAM circuit by the contact structures 190 connecting the unit devices in a desired way.

In view of the above, the semiconductor device in accordance with some embodiments includes the first insulation cut structures disposed between two adjacent gate structures and two adjacent epitaxial structures on different fin structures. The two adjacent epitaxial structures on different fin structures are isolated from each to prevent from the merge of the adjacent epitaxial structures. Therefore, the yield of the semiconductor devices is improved. In addition, the first insulation cut structures between the epitaxial structures are fabricated by the same processes of fabricating the second insulation cut structures cutting the gate structures, thus no extra process and fabrication burden are required.

In an aspect of the present disclosure, a semiconductor device including fin structures, gate structures, epitaxial structures and first insulation cut structures is provided. Each of the fin structures extends linearly and the gate structures linearly extends across the fin structures. The epitaxial structures are disposed on the fin structures and located beside the gate structures. The first insulation cut structures are disposed between the epitaxial structures, wherein two adjacent fin structures of the fin structures and two adjacent gate structures of the gate structures surrounds a closed region and one of the first insulation cut structures is located within the closed region. In some embodiments, a second insulation cut structure further extend parallel to the fin structures. The gate structures are isolated from each other by the second insulation cut structure. The second insulation cut structure includes a dielectric liner and a dielectric fill filling the dielectric liner. In some embodiments, each of the first insulation cut structures includes a dielectric liner and a dielectric fill surrounded by the dielectric liner. In some embodiments, contact structures are further located between the gate structures. At least one of the contact structures is in contact two of the epitaxial structures and the two of the epitaxial structures are disposed on different fin structures. In addition, one of the first insulation cut structures may be located between two of the contact structures.

In another aspect of the present disclosure, a semiconductor device including fin structures, gate structures, epitaxial structures and first insulation cut structures is provided. The fin structures are surrounded by an isolation structure on a substrate and each of the fin structures extends along a first direction. The gate structure extends along a second direction intersecting with the first direction and crossing the fin structures. The epitaxial structures are disposed on different fin structures at a same side of the gate structure. The first insulation cut structure is disposed between the epitaxial structures. In some embodiments, the first insulation cut structure extends toward the substrate to a level lower than bottoms of the epitaxial structures. In some embodiments, the first insulation cut structure extends toward the substrate to penetrate the isolation structure. In some embodiments, a mask layer is further disposed on the isolation structure and the first insulation cut structure extends toward the substrate to reach the mask layer. In some embodiments, a second insulation cut structure extends along the first direction, wherein the gate structure ends at the second insulation cut structure. In addition, the second insulation cut structure may extend toward the substrate to a level lower than the first insulation cut structure. In some embodiments, the first insulation cut structure includes a dielectric liner and a dielectric fill filling the dielectric liner. In some embodiments, the dielectric liner is made of a dielectric material different from the dielectric fill.

In yet another aspect of the present disclosure, a method of fabricating a semiconductor device provided herein includes forming fin structures on a substrate, wherein the fin structures are surrounded by an isolation structure and each of the fin structures extends along a first direction; forming a gate structure extending along a second direction intersected with the first direction and crossing the fin structures; forming epitaxial structures beside the gate structure on different fin structures; disposing a first insulation cut structure between the epitaxial structures; and disposing a second insulation cut structure extending along the first direction. In some embodiments, the gate structure ends at the second insulation cut structure. In some embodiments, the first insulation cut structure and the second insulation cut structure are formed through a feature cutting process. The feature cutting process may include forming recesses over the substrate and depositing a liner material layer and a filling material to fill the recesses. A planarization process is further performed until the gate structure is co-level with the first insulation cut structure and the second insulation cut structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
fin structures;
gate structures, each of the gate structures linearly extending across the fin structures;
epitaxial structures disposed on the fin structures and located beside the gate structures; and
first insulation cut structures, disposed between the epitaxial structures, wherein two adjacent fin structures of the fin structures and two adjacent gate structures of the gate structures surrounds a closed region and one of the first insulation cut structures is located within the closed region.

2. The semiconductor device of claim 1, further comprising a second insulation cut structure extending parallel to the fin structures.

3. The semiconductor device of claim 2, wherein the gate structures arranged in a column are isolated from each other by the second insulation cut structure.

4. The semiconductor device of claim 2, wherein the second insulation cut structure comprises a dielectric liner and a dielectric fill filling the dielectric liner.

5. The semiconductor device of claim 1, wherein each of the first insulation cut structures comprises a dielectric liner and a dielectric fill surrounded by the dielectric liner.

6. The semiconductor device of claim 1, further comprising contact structures located between the gate structures.

7. The semiconductor device of claim 6, wherein at least one of the contact structures is in contact two of the epitaxial structures and the two of the epitaxial structures are disposed on different fin structures.

8. The semiconductor device of claim 6, wherein one of the first insulation cut structures is located between two of the contact structures.

9. A semiconductor device, comprising:
fin structures, surrounded by an isolation structure on a substrate and each of the fin structures extending along a first direction;
a gate structure extending along a second direction intersecting with the first direction and crossing the fin structures;
epitaxial structures disposed on different fin structures at a same side of the gate structure; and
a first insulation cut structure disposed between the epitaxial structures.

10. The semiconductor device of claim 9, wherein the first insulation cut structure extends toward the substrate to a level lower than bottoms of the epitaxial structures.

11. The semiconductor device of claim 9, wherein the first insulation cut structure extends toward the substrate to penetrate the isolation structure.

12. The semiconductor device of claim 9, further comprising a hark mask layer disposed on the isolation structure and the first insulation cut structure extends toward the substrate to reach the hark mask layer.

13. The semiconductor device of claim 9, further comprising a second insulation cut structure extending along the first direction, wherein the gate structure ends at the second insulation cut structure.

14. The semiconductor device of claim 13, wherein the second insulation cut structure extends toward the substrate to a level lower than the first insulation cut structure.

15. The semiconductor device of claim 9, wherein the first insulation cut structure comprises a dielectric liner and a dielectric fill filling the dielectric liner.

16. The semiconductor device of claim 15, wherein the dielectric liner is made of a dielectric material different from the dielectric fill.

17. A method of fabricating a semiconductor device, comprising:
forming fin structures on a substrate, wherein the fin structures are surrounded by an isolation structure and each of the fin structures extends along a first direction;
forming a gate structure extending along a second direction intersected with the first direction and crossing the fin structures;
forming epitaxial structures beside the gate structure on different fin structures;
disposing a first insulation cut structure between the epitaxial structures; and
disposing a second insulation cut structure extending along the first direction, wherein the first insulation cut structure and the second insulation cut structure are formed through a feature cutting process.

18. The method of claim 17, wherein the gate structure is cut from gate features by the feature cutting process.

19. The method of claim 17, wherein the feature cutting process comprises forming recesses over the substrate and depositing a liner material layer and a filling material to fill the recesses.

20. The method of claim 19, further comprising performing a planarization process until the gate structure is co-level with the first insulation cut structure and the second insulation cut structure.
